(19) United States
(12) Patent Application Publication
(10) Pub. No.: US 2019/0287893 A1
(43) Pub. Date: Sep. 19, 2019

(54) WIRING SUBSTRATE, SEMICONDUCTOR MODULE, AND MANUFACTURING METHOD FOR WIRING SUBSTRATE

(71) Applicant: FUJITSU LIMITED, Kawasaki-shi (JP)

(72) Inventor: Daisuke Mizutani, Sagamihara (JP)

(73) Assignee: FUJITSU LIMITED, Kawasaki-shi (JP)

(21) Appl. No.: 16/297,962

(22) Filed: Mar. 11, 2019

(30) Foreign Application Priority Data
Mar. 19, 2018 (JP) 2018-051135

(51) Int. Cl. H01L 23/522; H01L 49/02; H01L 23/48; H01L 21/768

(52) U.S. Cl. CPC H01L 23/5223; H01L 28/60; H01L 21/76898; H01L 23/5226; H01L 23/481

(57) ABSTRACT

A wiring substrate includes, a base substrate, a film capacitor, a first through via and a second through via. The film capacitor includes a first conductive film disposed on a surface of the base substrate, a second conductive film, and a dielectric film disposed between the first conductive film and the second conductive film. The first through via disposed in the base substrate, penetrates the base substrate and the capacitor, is electrically coupled to the second conductive film, and is insulated from the first conductive film. The second through via disposed in the base substrate, penetrates the base substrate, is electrically coupled to the first conductive film, and is insulated from the second conductive film.

### CROSS-REFERENCE TO RELATED APPLICATION

This application is based upon and claims the benefit of priority of the prior Japanese Patent Application No. 2018-51135, filed on Mar. 19, 2018, the entire contents of which are incorporated herein by reference.

### FIELD

The embodiments discussed herein are related to a wiring substrate, a semiconductor module, and a manufacturing method for the wiring substrate.

### BACKGROUND

As a technique related to a wiring substrate having a capacitor, for example, the following technique is known. For example, a wiring substrate is known which includes a capacitor having a dielectric layer formed on a first electrode layer and a second electrode layer formed on the dielectric layer, and multiple via wires that are coupled to the first electrode layer or the second electrode layer, and formed to penetrate the capacitor.

A wiring substrate is known which includes a first electrode, a second electrode, and a capacitor provided between the first and second electrodes. In the wiring substrate, the first electrode includes an opening to form a second via. The second electrode includes an opening for each of first and second vias. The dielectric includes an opening for each of the first and second vias.

Related techniques are disclosed in, for example, Japanese Laid-open Patent Publication Nos. 2006-173494 and 2007-184324.

### SUMMARY

According to an aspect of the embodiments, a wiring substrate includes, a base substrate, a film capacitor, a first through via and a second through via. The film capacitor includes a first conductive film disposed on a surface of the base substrate, a second conductive film, and a dielectric film disposed between the first conductive film and the second conductive film. The first through via disposed in the base substrate, penetrates the base substrate and the capacitor, is electrically coupled to the second conductive film, and is insulated from the first conductive film. The second through via disposed in the base substrate, penetrates the base substrate, is electrically coupled to the first conductive film, and is insulated from the second conductive film.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a cross-sectional view schematically illustrating the configuration of a wiring substrate according to an embodiment of the technique of the present disclosure;

FIG. 2 is a cross-sectional view illustrating an example of the configuration of the wiring substrate according to the embodiment of the technique of the present disclosure;

FIG. 3 is a plan view schematically illustrating the positional relationship between a capacitor and a first through via according to the embodiment of the technique of the present disclosure;

FIG. 4A is a cross-sectional view illustrating an example of a method of manufacturing the wiring substrate according to the embodiment of the technique of the present disclosure;

FIG. 4B is a cross-sectional view illustrating an example of the method of manufacturing the wiring substrate according to the embodiment of the technique of the present disclosure;

FIG. 4C is a cross-sectional view illustrating an example of the method of manufacturing the wiring substrate according to the embodiment of the technique of the present disclosure;

FIG. 4D is a cross-sectional view illustrating an example of the method of manufacturing the wiring substrate according to the embodiment of the technique of the present disclosure;

FIG. 4E is a cross-sectional view illustrating an example of the method of manufacturing the wiring substrate according to the embodiment of the technique of the present disclosure;

FIG. 4F is a cross-sectional view illustrating an example of the method of manufacturing the wiring substrate according to the embodiment of the technique of the present disclosure;

FIG. 4G is a cross-sectional view illustrating an example of the method of manufacturing the wiring substrate according to the embodiment of the technique of the present disclosure;

FIG. 4H is a cross-sectional view illustrating an example of the method of manufacturing the wiring substrate according to the embodiment of the technique of the present disclosure;

FIG. 4I is a cross-sectional view illustrating an example of the method of manufacturing the wiring substrate according to the embodiment of the technique of the present disclosure;

FIG. 4J is a cross-sectional view illustrating an example of the method of manufacturing the wiring substrate according to the embodiment of the technique of the present disclosure;

FIG. 4K is a cross-sectional view illustrating an example of the method of manufacturing the wiring substrate according to the embodiment of the technique of the present disclosure;

FIG. 4L is a cross-sectional view illustrating an example of the method of manufacturing the wiring substrate according to the embodiment of the technique of the present disclosure;

FIG. 4M is a cross-sectional view illustrating an example of the method of manufacturing the wiring substrate according to the embodiment of the technique of the present disclosure;

FIG. 4N is a cross-sectional view illustrating an example of the method of manufacturing the wiring substrate according to the embodiment of the technique of the present disclosure;

FIG. 4O is a cross-sectional view illustrating an example of the method of manufacturing the wiring substrate according to the embodiment of the technique of the present disclosure;

FIG. 5 is a cross-sectional view illustrating the configuration of a wiring substrate according to a comparative example;

FIG. 6A is a cross-sectional view illustrating an example of a method of manufacturing the wiring substrate according to the comparative example;

FIG. 6B is a cross-sectional view illustrating an example of the method of manufacturing the wiring substrate according to the comparative example;

FIG. 6C is a cross-sectional view illustrating an example of the method of manufacturing the wiring substrate according to the comparative example;

FIG. 6D is a cross-sectional view illustrating an example of the method of manufacturing the wiring substrate according to the comparative example;

FIG. 6E is a cross-sectional view illustrating an example of the method of manufacturing the wiring substrate according to the comparative example;

FIG. 6F is a cross-sectional view illustrating an example of the method of manufacturing the wiring substrate according to the comparative example;

FIG. 6G is a cross-sectional view illustrating an example of the method of manufacturing the wiring substrate according to the comparative example;

FIG. 6H is a cross-sectional view illustrating an example of the method of manufacturing the wiring substrate according to the comparative example;

FIG. 6I is a cross-sectional view illustrating an example of the method of manufacturing the wiring substrate according to the comparative example;

FIG. 6J is a cross-sectional view illustrating an example of the method of manufacturing the wiring substrate according to the comparative example;

FIG. 6K is a cross-sectional view illustrating an example of the method of manufacturing the wiring substrate according to the comparative example;

FIG. 6L is a cross-sectional view illustrating an example of the method of manufacturing the wiring substrate according to the comparative example;

FIG. 6M is a cross-sectional view illustrating an example of the method of manufacturing the wiring substrate according to the comparative example;

FIG. 7A is a plan view schematically illustrating the openings formed in a second conductive film of a capacitor in the wiring substrate according to the comparative example;

FIG. 7B is a plan view schematically illustrating the openings formed in a first conductive film of the capacitor in the wiring substrate according to the comparative example;

FIG. 7C is a plan view schematically illustrating an effective area of the capacitor in the wiring substrate according to the comparative example;

FIG. 8 is a cross-sectional view illustrating an example of the configuration of the wiring substrate according to the embodiment of the technique of the present disclosure; and

FIG. 9 is a cross-sectional view illustrating an example of the configuration of a semiconductor module according to an embodiment of the technique of the present disclosure.

### DESCRIPTION OF EMBODIMENTS

Race of development of a central processing unit (CPU) for high-end computers is highly intense, and due to demand for high performance, upsizing and enhanced speed of CPU are being pursued. Primary factors for improvement of the performance of CPU are increase in the number of transistors and increase in the transmission speed. Accordingly, the power consumption of CPU increases and the chip size is also increased. When the performance of CPU improves, naturally, it is expected that the performance of a computer using the CPU improves. However, in order to utilize a CPU as a device, semiconductor chips included in the CPU have to be mounted on a multi-layer wiring substrate called a package substrate to form a CPU module. Consequently, to implement a high-performance computer, it is preferable to develop a high-performance package substrate in order to serve each CPU as a device without impairing the performance of the CPU.

There are multiple challenges when the performance of a CPU is attempted to be maximized as a high-performance CPU module. One of the challenges is to reduce power supply variation noise generated when a current flows through a semiconductor chip included in a CPU. The significance of the challenge is increasing for achieving not only high performance of CPU but also a low operation voltage to reduce power consumption. It's not an exaggeration to state that the reduction of power supply variation noise is the greatest challenge in the case where a great number of transistors are built in, and a high current is desirable particularly in a CPU for high-end computers.

Thus, an approach of embedding a chip decoupling capacitor into an area just below a CPU inside a package substrate has been discussed. However, the area just below a CPU inside a package substrate is also used as a current supply path to the CPU. When a power supply penetrating a package substrate and a through via to the ground are disposed in the area just below the CPU of the package substrate, it is difficult to dispose a decoupling capacitor in the area just below the CPU. Therefore, a decoupling capacitor has to be disposed at a position away from the area just below the CPU, and in this case, it is difficult to achieve a sufficient noise reduction effect.

Thus, use of a thin film capacitor as a decoupling capacitor is being studied. The thin film capacitor has a three-layer structure in which an electrode is formed on the front and back of a highly dielectric film with a thickness of 1 μm or less. It is possible to perform processing on the thin film capacitor to form a through hole that penetrates the electrode and the dielectric film. Consequently, disposing of the thin film capacitor in the area just below the CPU of the package substrate enables formation of a through via in the area just below the CPU as well as the shortest distance between the CPU and the decoupling capacitor.

When a thin film capacitor is used as the decoupling capacitor, one of the electrodes of the thin film capacitor has to be coupled to the power supply potential, and the other electrode has to be coupled to the ground potential. Thus, the electrode of the thin film capacitor coupled to the ground potential has to be insulated by providing clearance for a through via to which the power supply potential is supplied. Similarly, the electrode of the thin film capacitor coupled to the power supply potential has to be insulated by providing clearance for a through via to which the ground potential is supplied.

In the thin film capacitor, the area in which one electrode and the other electrode overlap provides an effective area that serves as a capacitor. For this reason, when clearance for the through via is provided in both electrodes, the effective area is reduced. As a consequence, the cost of the capacitor in the package substrate increases.

Hereinafter, an example of an embodiment of the technique of the present disclosure will be described with reference to the drawings. It is to be noted that the same or equivalent components and sections are labeled with the same symbol.

### First Embodiment

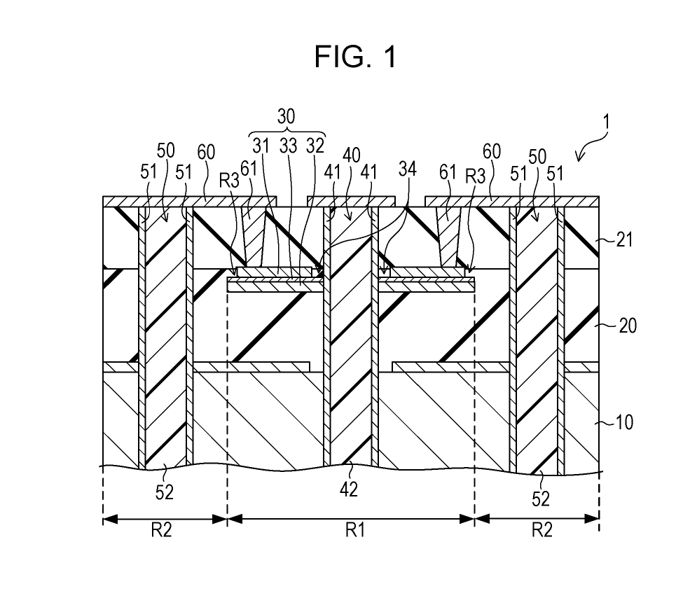

FIG. 1 is a cross-sectional view schematically illustrating the configuration of a wiring substrate 1 according to an embodiment of the technique of the present disclosure. The wiring substrate 1 includes a base substrate 10 that includes a fiber reinforced resin in which a glass fiber fabric is impregnated with an epoxy resin; and a thin film capacitor 30 provided on the surface of base substrate 10 with an insulating film 20 interposed therebetween. In short, the wiring substrate 1 is a capacitor built-in substrate.

The capacitor 30 includes a first conductive film 31 disposed outwardly in a thickness direction of the base substrate 10; a second conductive film 32 disposed inwardly in the thickness direction of the base substrate 10; and a dielectric film 33 provided between the first conductive film 31 and the second conductive film 32. The first conductive film 31 serves as one electrode of the capacitor 30. As an example, the first conductive film 31 includes nickel (Ni) having a thickness of approximately 20 μm. The second conductive film 32 serves as the other electrode of the capacitor 30. As an example, the second conductive film 32 includes copper (Cu) having a thickness of approximately 20 μm. As an example, the dielectric film 33 includes barium titanate (BTO) having a thickness of approximately 1 μm. The outer size of the capacitor 30 is smaller than the outer size of the base substrate 10. For example, the wiring substrate 1 has a non-formation area R2 of the capacitor 30 on each outer side of a formation area R1 of the capacitor 30. The surface of the capacitor 30 is covered with an insulating film 21.

The wiring substrate 1 has a first through via 40 that penetrates the insulating film 21, the capacitor 30, the insulating film 20, and the base substrate 10 which are provided in the formation area R1 of the capacitor 30. The first through via 40 is formed by forming a conductive film 41 on the inner wall of a through hole which penetrates the insulating film 21, the capacitor 30, the insulating film 20, and the base substrate 10. The inside of the through hole is filled with an insulating material 42 such as an epoxy resin. The conductive film 41 of the first through via 40 is electrically coupled to the second conductive film 32 of the capacitor 30, and is insulated from the first conductive film 31 of the capacitor 30. The second conductive film 32 of the capacitor 30 is bonded to the dielectric film 33 over the entire surface of the dielectric film 33. On the other hand, the first conductive film 31 of the capacitor 30 is bonded the dielectric film 33 with a gap (clearance) 34 between the first through via 40 and the first conductive film 31. In the wiring substrate 1, the through via penetrating the capacitor 30 is formed of only the first through via 40 that is electrically coupled to the second conductive film 32, and is insulated from the first conductive film 31.

The wiring substrate 1 has a second through via 50 that is provided in each non-formation area R2 (in other words, on outer sides of the capacitor 30) of the capacitor 30 and penetrates the insulating films 21, 20 and the base substrate 10. The second through via 50 is formed by forming a conductive film 51 on the inner wall of a through hole which penetrates the insulating films 21, 22, and the base substrate 10. The inside of the through hole is filled with an insulating material 52 such as an epoxy resin. The conductive film 51 of the second through via 50 is electrically coupled to the first conductive film 31 of the capacitor 30, and is insulated from the second conductive film 32 of the capacitor 30.

The surface of the insulating film 21 is provided with connection wires 60 which are electrically coupled to the conductive film 51 of the second through via 50. The inside of the insulating film 21 is provided with multiple interstitial via holes (IVH) 61 that electrically connect the connection wire 60 and the first conductive film 31 of the capacitor 30. For example, the second through via 50 is electrically coupled to first conductive film 31 of the capacitor 30 via the connection wires 60 and the multiple IVHs 61.

For example, a power supply potential is applied to the first through via 40, and for example, a ground potential is applied to the second through via 50. Therefore, the power supply potential is applied to the second conductive film 32 of the capacitor 30 via the first through via 40, and the ground potential is applied to the first conductive film 31 of the capacitor 30 via the second through via 50. For example, the capacitor 30 may function as a decoupling capacitor.

The capacitor 30 has an area R3 in its periphery, where the first conductive film 31 is not formed. For example, the periphery of the capacitor 30 has a two-layer structure including the dielectric film 33 and the second conductive film 32. With this structure, it is possible to reduce the risk of occurrence of short-circuit between the power supply and the ground due to contact between the first conductive film 31 and the second conductive film 32 at an end face of the capacitor 30. It is to be noted that a ring-shaped groove, which divides the outer periphery and the inner periphery of the first conductive film 31, may be provided along the outer periphery of the first conductive film 31. With this structure, it is possible to avoid occurrence of short-circuit between the power supply and the ground even when the outer periphery of the first conductive film 31 and the second conductive film 32 come into contact with each other at an end face of the capacitor 30.

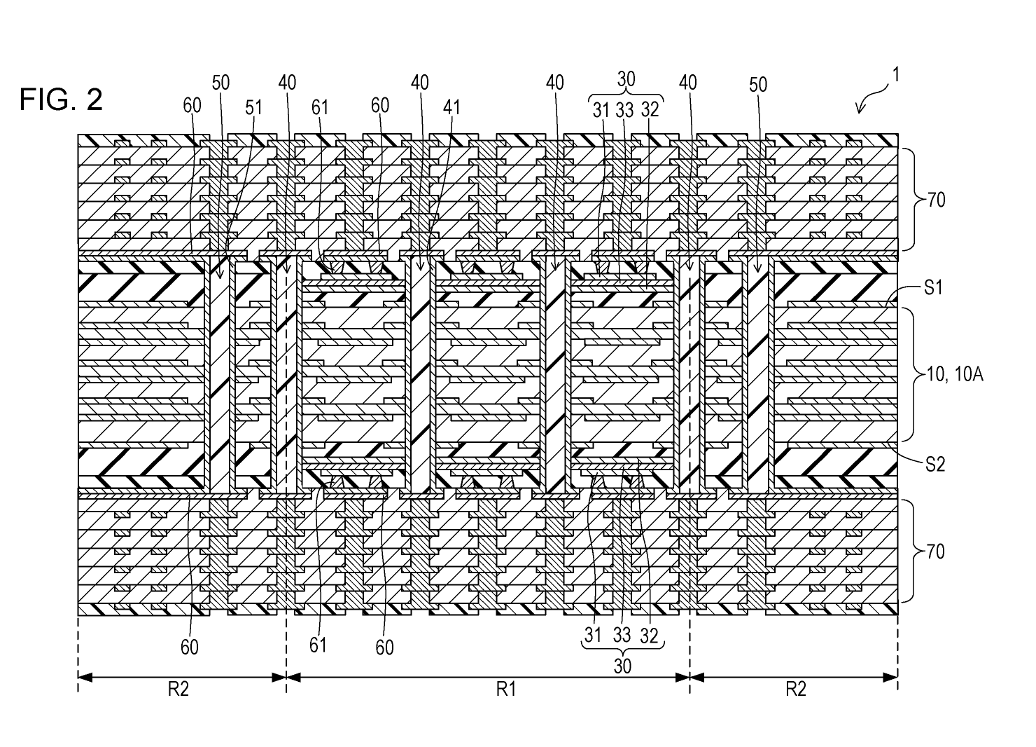

FIG. 2 is a cross-sectional view illustrating an example of a specific configuration of the wiring substrate 1. The wiring substrate 1 includes the base substrate 10 as a core layer 10A, and may have a form of build-up substrate in which multiple build-up layers 70 are provided near the first surface S1 of the base substrate 10 and near the second surface S2 opposite to the first surface S1 of the base substrate 10.

The core layer 10A is formed by alternately stacking a copper clad laminate (CCL) and a prepreg. The example of FIG. 2 illustrates the core layer 10A having eight wiring layers.

The multiple build-up layers 70 are formed by repeating formation of a prepreg, hole making process, and formation of a wire. The example of FIG. 2 illustrates a configuration in which six build-up layers 70 are stacked on both sides of the core layer 10A. In the example illustrated in FIG. 2, the thin film capacitor 30 is provided near the first surface S1 and near the second surface S2 of the base substrate 10 which serves as the core layer 10A.

The wiring substrate 1 has multiple first through vias 40 that penetrate the core layer 10A and the capacitor 30 which are provided in the formation area R1 of the capacitor 30. The conductive film 41 of each of the multiple first through vias 40 is electrically coupled to the second conductive film 32 of the capacitor 30, and is insulated from the first conductive film 31 of the capacitor 30.

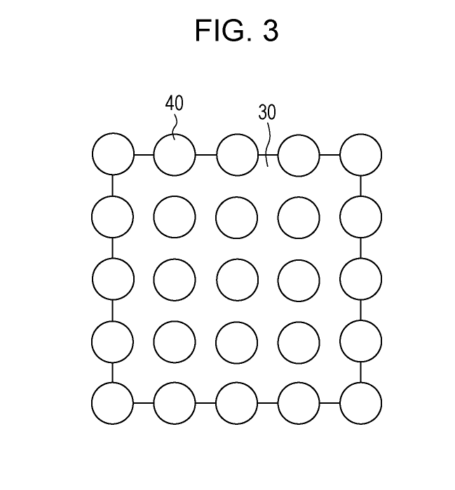

FIG. 3 is a plan view schematically illustrating the positional relationship between the capacitor 30 and the first through vias 40. As illustrated in FIG. 3, part of multiple first through vias 40 is provided at the position corresponding to the outer periphery of the capacitor 30 so as to pass through the outer periphery of the capacitor 30.

The wiring substrate 1 has multiple second through vias 50 that are provided in the non-formation area R2 (in other words, the outer sides of the capacitor 30) of the capacitor 30 and penetrate the core layer 10A. The conductive film 51 of each of the multiple second through vias 50 is electrically coupled to the first conductive film 31 of the capacitor 30 via the connection wires 60 and the multiple IVH 61 formed on both sides of the core layer 10A. In FIG. 2, in each connection wire 60, a portion coupled to the second through via 50 and a portion coupled to the IVH 61 are mutually divided. However, these portions are coupled to each other at a cross-section different from the cross-section illustrated in FIG. 2. The conductive film 51 of each of the multiple second through vias 50 is insulated from second conductive film 32 of the capacitor 30.

The capacitors 30, provided near the first surface S1 and near the second surface S2 of the base substrate 10 which serves as the core layer 10A, are coupled in parallel via the first through via 40 and the second through via 50.

The interval between the multiple IVHs 61 is smaller than the interval between multiple first through vias 40. The number of multiple IVHs 61 is larger than the number of multiple first through vias 40. For example, the multiple IVHs 61 are formed with a higher density than that of the multiple first through vias 40.

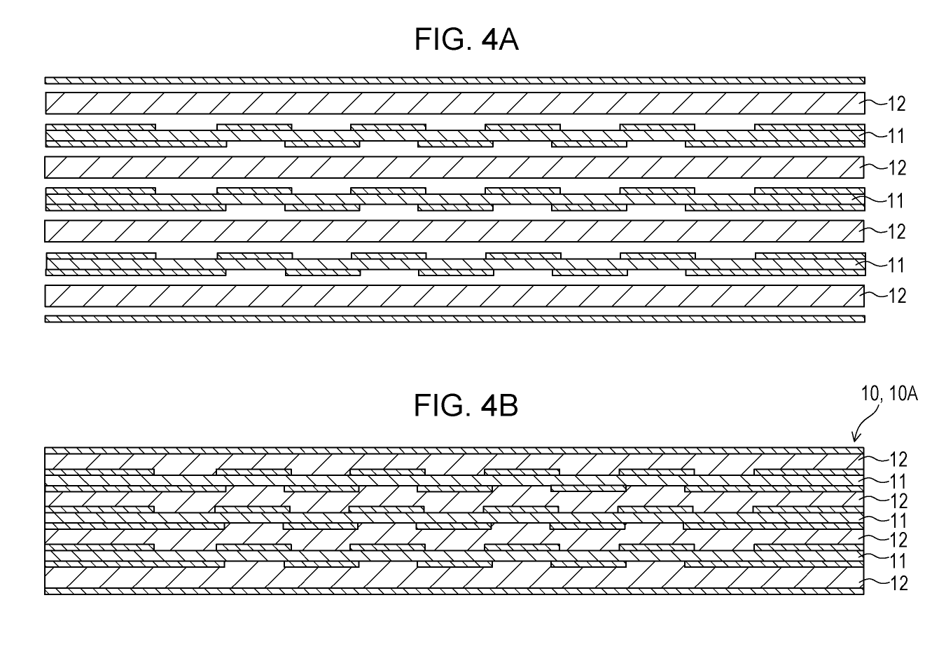

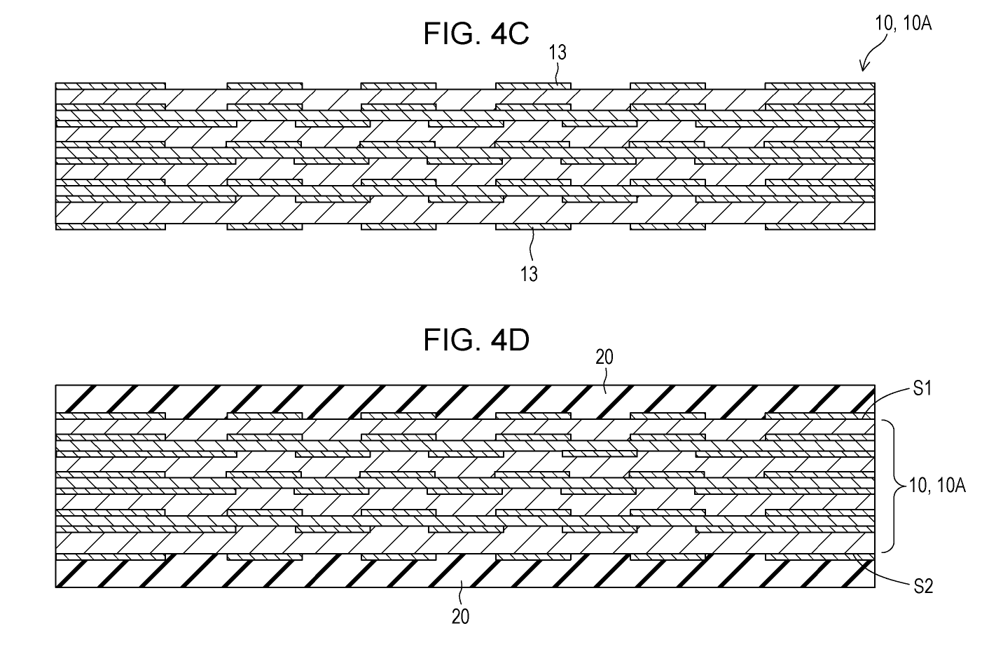

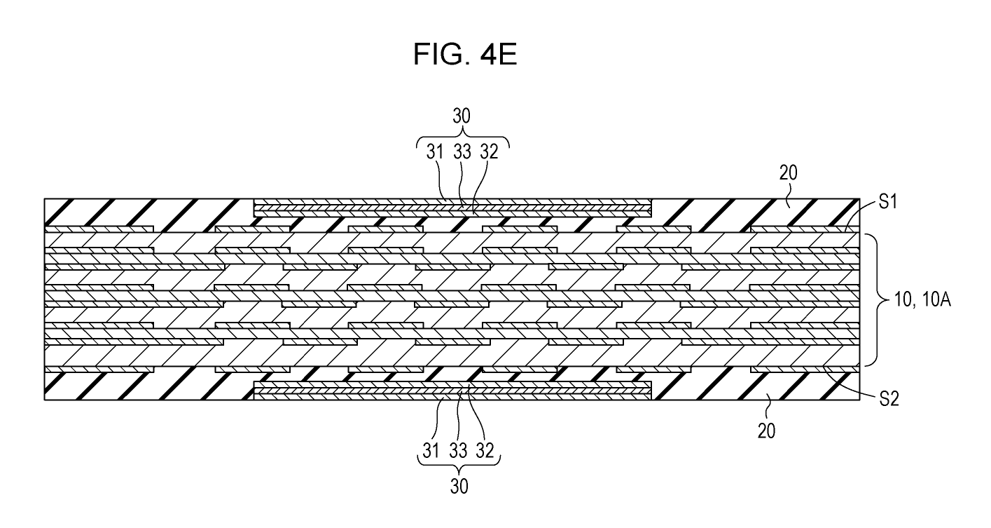

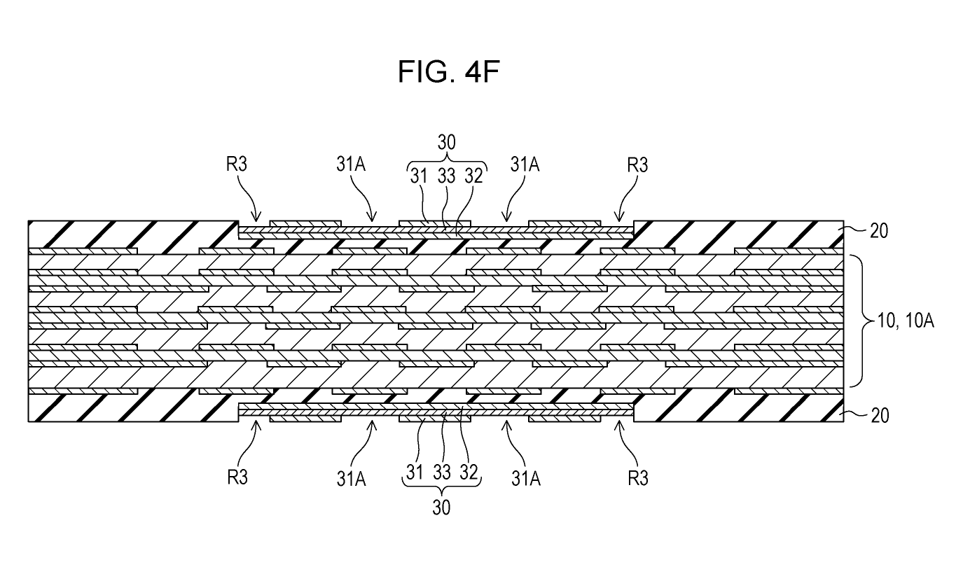

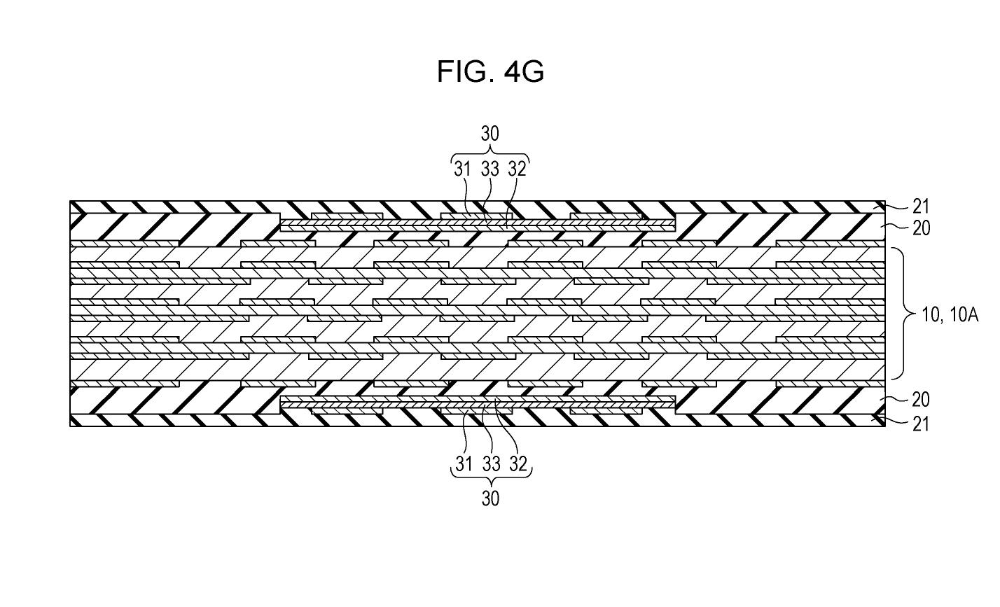

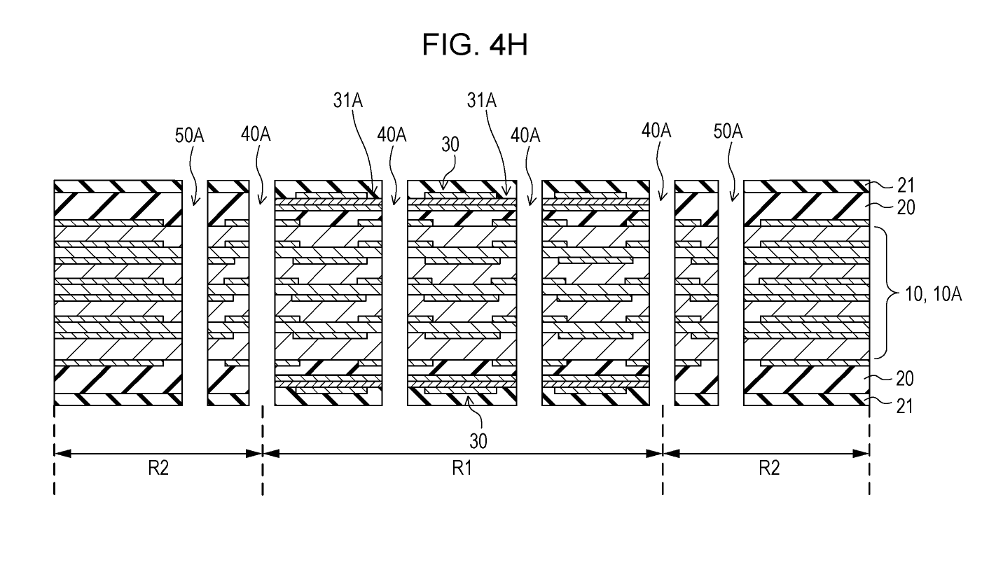

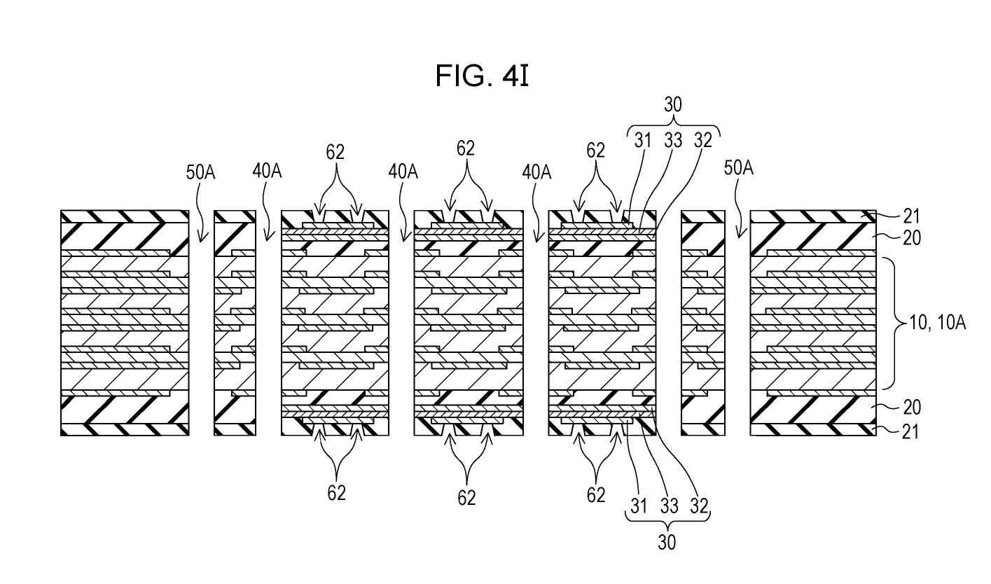

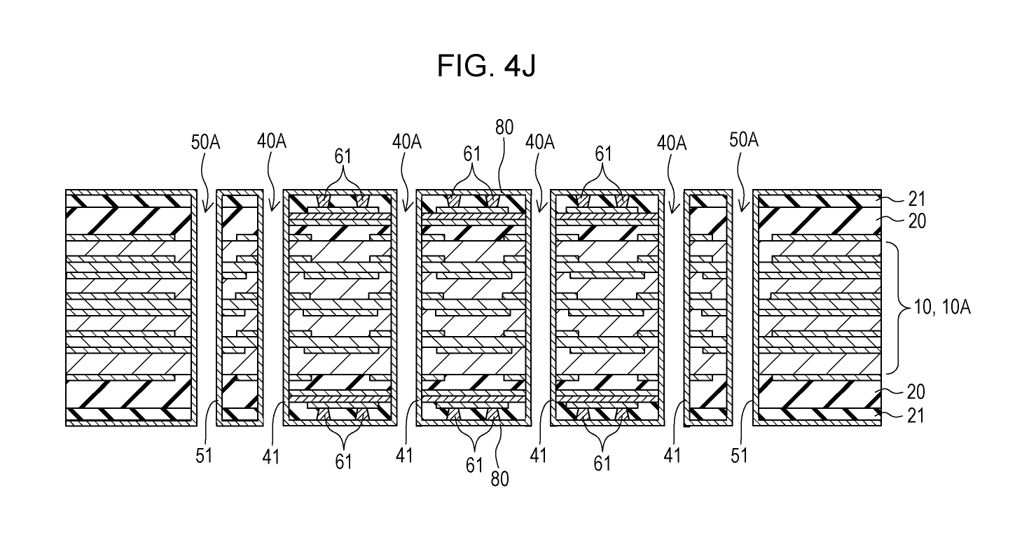

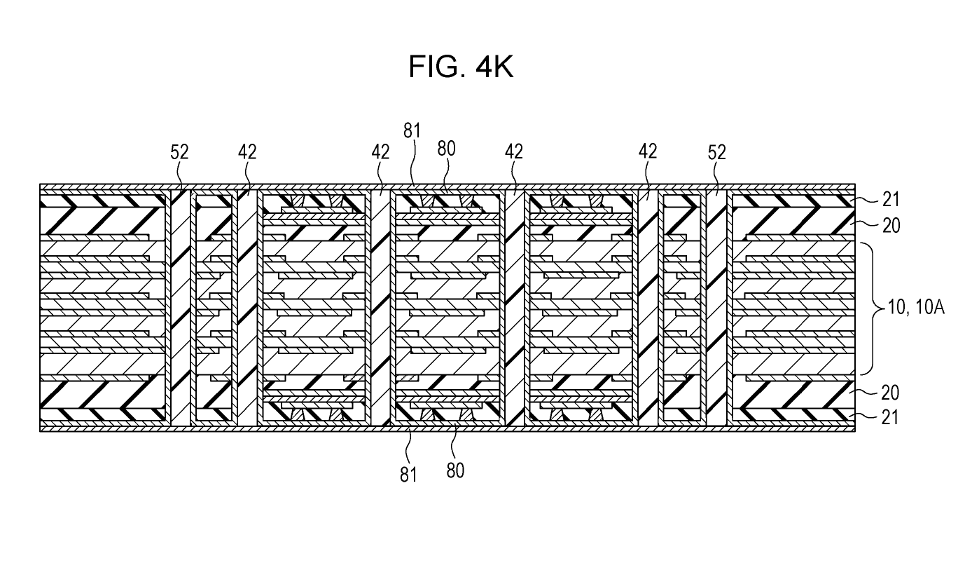

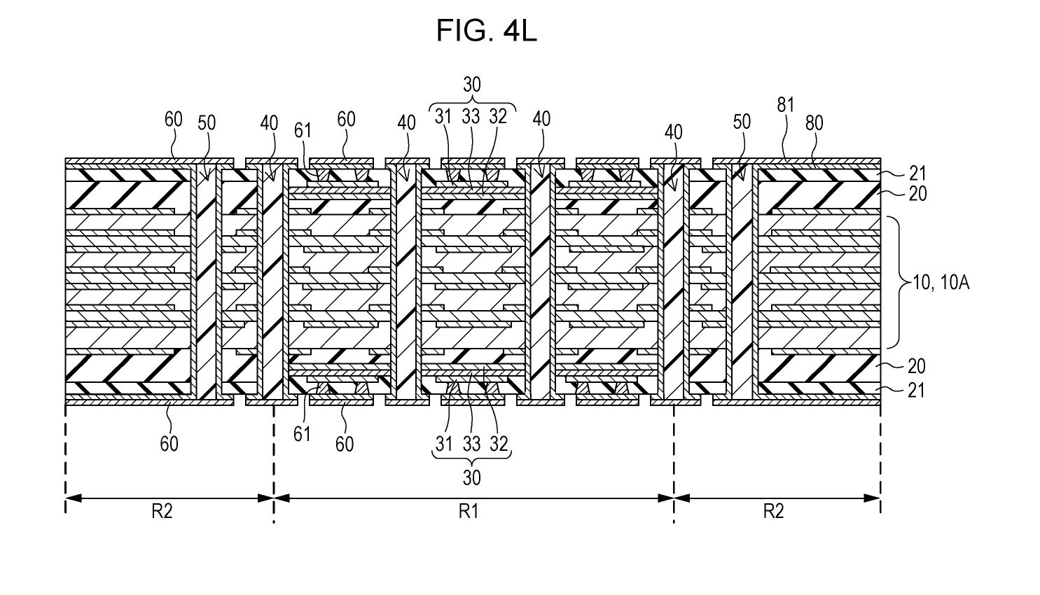

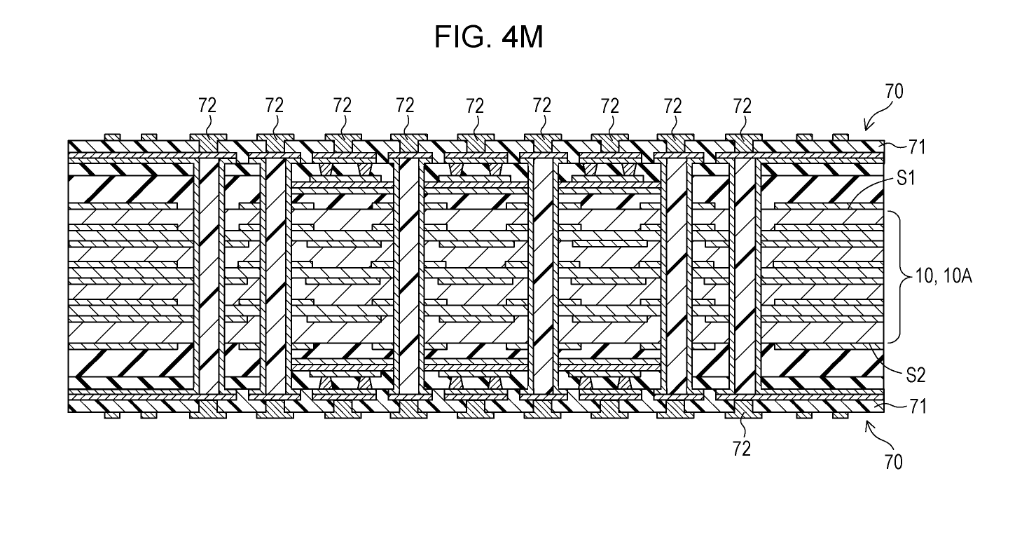

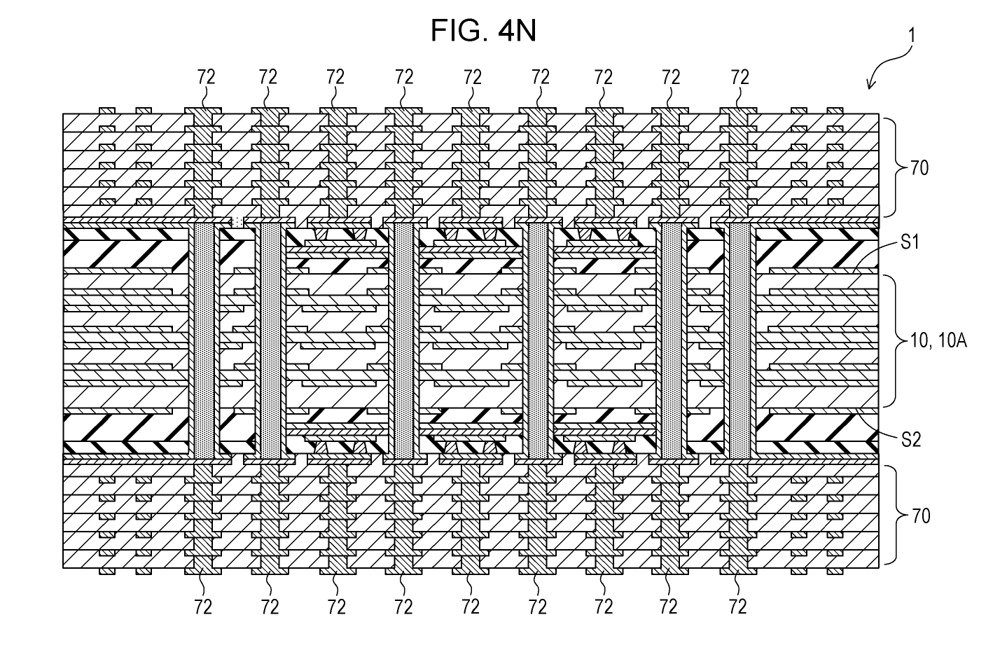

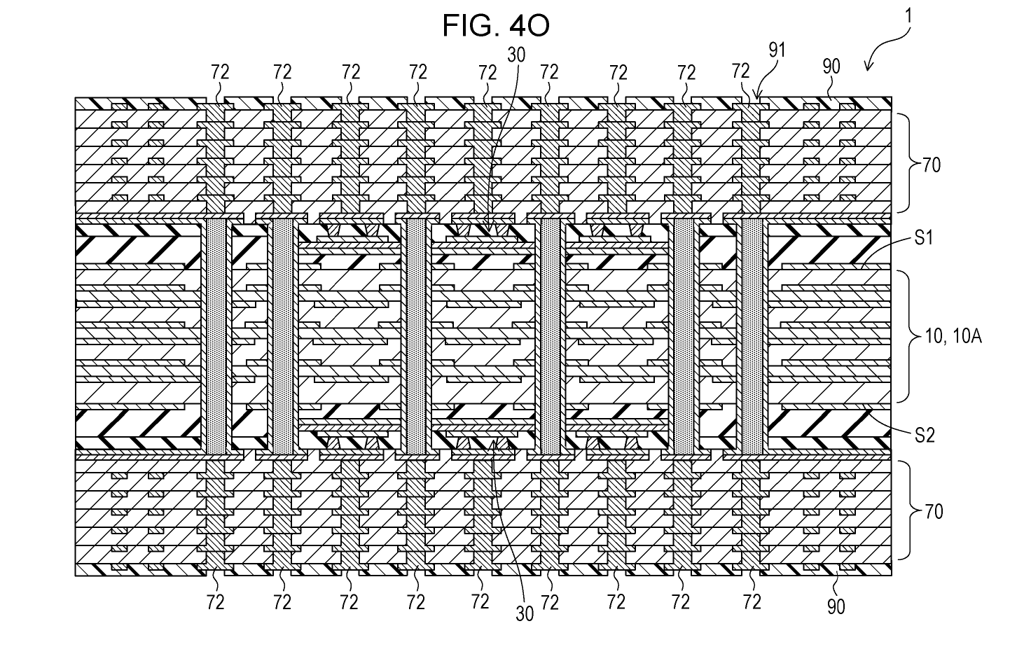

Hereinafter, a method of manufacturing the wiring substrate 1 according to the embodiment of the technique of the present disclosure will be described. FIGS. 4A to 4O are each a cross-sectional view illustrating an example of the method of manufacturing the wiring substrate 1.

First, the base substrate 10, which serves as the core layer 10A, is produced by stacking a CCL 11 and a prepreg 12 alternately as illustrated in FIG. 4A (FIG. 4B). The CCL 11 is produced in the following manner: a conductive film such as copper foil is affixed to the front and the back of a fiber reinforced resin in which a glass fiber fabric is impregnated with an epoxy resin, and the conductive film is patterned. For example, E679FGR manufactured by Hitachi Chemical may be used as the fiber reinforced resin included in the CCL 11. Subsequently, a conductive film 13 formed on the outermost surface of the base substrate 10 is patterned (FIG. 4C).

Subsequently, the insulating film 20 is formed, for example, by a vacuum lamination method on each of the first surface S1 and the second surface S2 of the base substrate 10 which serves as the core layer 10A. For example, GZ-41 manufactured by Ajinomoto may be used as the insulating film 20 (FIG. 4D).

Subsequently, a thin film capacitor 30, which is cut in a square with a side of approximately 20 mm for example, is disposed on the insulating film 20. The capacitor 30 includes a first conductive film 31 disposed outwardly in a thickness direction of the base substrate 10; a second conductive film 32 disposed inwardly in the thickness direction of the base substrate 10; and a dielectric film 33 provided between the first conductive film 31 and the second conductive film 32. The capacitor 30 is disposed at the center of the base substrate 10 on both sides, that is, near the first surface S1 and near the side of the second surface S2 of the base substrate 10 which serves as the core layer 10A. Subsequently, the surface of the capacitor 30 is protected by a polyethyleneterephthalate (PET) film (not illustrated), then the capacitor 30 is brought into intimate contact with the insulating film 20, for example, by a vacuum lamination method. Next, the PET film is peeled off, then the insulating film 20 is thermally cured (FIG. 4E).

Subsequently, the first conductive film 31 of the capacitor 30, disposed outwardly in a thickness direction of the base substrate 10 is patterned. Openings 31A are formed in the first conductive film 31, each having a diameter greater than the diameter of the first through via 40 formed in the later process so that gap (clearance) is created between the first conductive film 31 and the first through via 40. The outer periphery of the first conductive film 31 is removed. Consequently, the capacitor 30 has an area R3, in which the first conductive film 31 is not formed, on the outer periphery, which has a two-layer structure including the dielectric film 33 and the second conductive film 32 (FIG. 4F).

Subsequently, the insulating film 21 is formed on the surface of the base substrate 10 which serves as the core layer 10A. The surface of the capacitor 30 is covered with the insulating film 21. For example, GZ-41 manufactured by Ajinomoto may be used as the insulating film 21. Subsequently, the insulating film 21 is thermally cured (FIG. 4G).

Subsequently, multiple through holes 40A included in the multiple first through vias 40 and multiple through holes 50A included in the multiple second through vias 50 are formed by drilling. Each of the multiple through holes 40A is formed in the formation area R1 of the capacitor 30, and penetrates the base substrate 10 along with the insulating films 21, 20 and the capacitor 30 provided on both sides of the base substrate 10. Part of the multiple through holes 40A is provided at the position corresponding to the opening 31A so as to pass through the opening 31A formed in the first conductive film 31. The other part of the multiple through holes 40A is provided at the position corresponding to the outer periphery of the capacitor 30 so as to pass through the outer periphery of the capacitor 30. Each of the multiple through holes 50A is formed in the non-formation area R2 of the capacitor 30, in other words, formed on the outer sides of the capacitor 30, and penetrates the base substrate 10 along with the insulating films 21, 20 provided on both sides of the base substrate 10 (FIG. 4H).

Subsequently, multiple openings 62, which reach the first conductive film 31 of the capacitor 30, are formed in the insulating film 21 by laser machining. The multiple openings 62 form the multiple IVHs 61. The multiple openings 62 are formed with a higher density than that of the multiple through holes 40A (FIG. 4I).

Subsequently, a conductive material such as copper is embedded in each of the multiple openings 62 by plating processing, thereby forming the multiple IVHs 61. The conductive films 41, 51, which cover the inner walls of the through holes 40A, 50A, respectively, are formed by the plating processing. A conductive film 80 is further formed on the surface of the insulating film 21 by the plating processing (FIG. 4J).

Subsequently, the insides of the through holes 40A, 50A are filled with the insulating materials 42 and 52 such as an epoxy resin. Subsequently, a conductive film 81, which covers the entire surface of the insulating film 21, is formed by plating processing so as to close the opening ends of the through holes 40A, 50A (FIG. 4K).

Subsequently, the conductive films 80 and 81 are patterned. Consequently, the first through via 40, which is electrically coupled to the second conductive film 32 of the capacitor 30, and is insulated from the first conductive film 31 of the capacitor 30, is formed in the formation area R1 of the capacitor 30. The second through via 50, which is electrically coupled to the first conductive film 31 of the capacitor 30 via the connection wire 60 and the IVH 61, and is insulated from the second conductive film 32 of the capacitor 30, is formed in each non-formation area R2 of the capacitor 30 (FIG. 4L). The connection wire 60 is formed by patterning the conductive films 80 and 81.

Subsequently, build-up layers 70 are formed on both sides, that is, near the first surface S1 and near the second surface S2 of the base substrate 10 which serves as the core layer 10A. Each build-up layer 70 is formed by formation of the prepreg 71, hole making process, and formation of the wire 72 (FIG. 4M). Multiple build-up layers 70 are stacked on both sides of the core layer 10A as desired. The first through via 40 and the second through via 50 are drawn to the outermost surface of the wiring substrate 1 by wires 72 provided in the build-up layers 70 (FIG. 4N).

Subsequently, a solder resist 90 is formed on the outermost surface of the build-up layers 70. Subsequently, the wires 72 provided on the outermost surface of the build-up layers 70 are exposed by forming openings 91 in the solder resist 90 (FIG. 4O). As a consequence of the above-described processes, the wiring substrate 1 including thin film capacitors 30 and the multiple build-up layers 70 is completed on both sides of the core layer 10A.

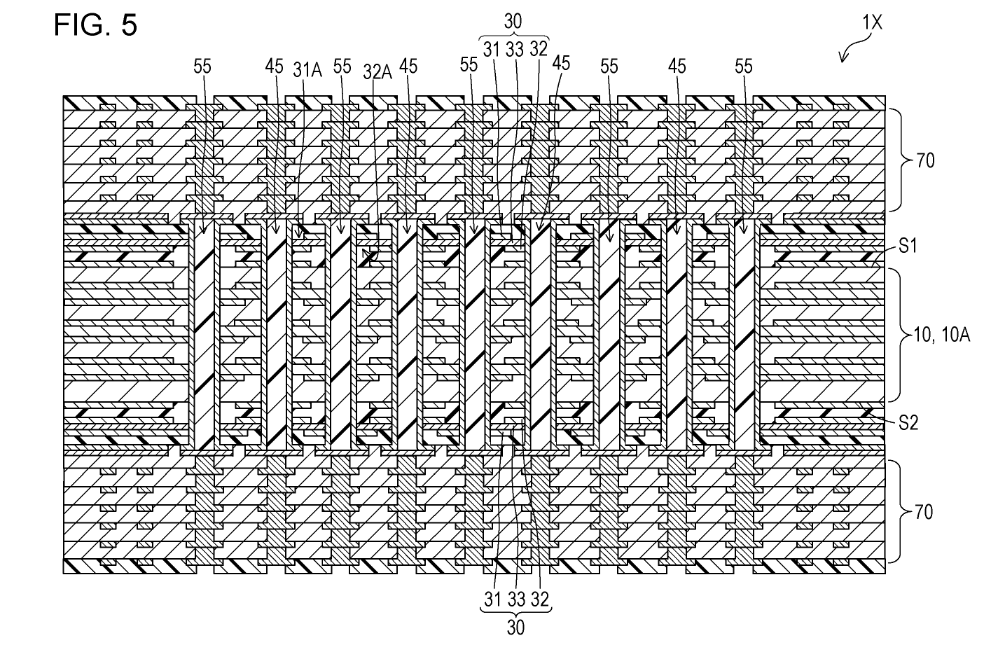

FIG. 5 is a cross-sectional view illustrating the configuration of a wiring substrate 1X according to a comparative example. Similarly to wiring substrate 1 according to the embodiment of the technique of the present disclosure, the wiring substrate lx according to the comparative example is a capacitor built-in substrate that includes thin film capacitors 30. The wiring substrate 1X according to the comparative example has a form of build-up substrate in which build-up layers 70 are provided on both sides of the base substrate 10 which serves as the core layer 10A.

Each thin film capacitor 30 has a first conductive film 31 disposed outwardly in a thickness direction of the base substrate 10; a second conductive film 32 disposed inwardly in the thickness direction of the base substrate 10; and a dielectric film 33 provided between the first conductive film 31 and the second conductive film 32. The capacitor 30 is provided near the first surface S1 and near the second surface S2 of the base substrate 10 which serves as the core layer 10A. The outer size of the capacitor 30 is substantially the same as the outer size of the base substrate 10, and the capacitor 30 covers substantially the entire surface of the base substrate 10. In the wiring substrate 1X according to the comparative example, the power supply potential is applied to the second conductive film 32, and the ground potential is applied to the first conductive film 31.

The wiring substrate 1X according to the comparative example has multiple through vias 45, 55 that penetrate the capacitor 30 and the core layer 10A. Of the multiple through vias 45, 55, the through vias 45, to which the power supply potential is supplied, are electrically coupled to the second conductive film 32 of the capacitor 30, and are insulated from the first conductive film 31 of the capacitor 30. Of the multiple through vias 45, 55, the through vias 55, to which the ground potential is supplied, are electrically coupled to the first conductive film 31 of the capacitor 30, and are insulated from the second conductive film 32 of the capacitor 30.

The first conductive film 31 of the capacitor 30 has openings 31A having a diameter greater than the diameter of each through via 45 to which the power supply potential is supplied so that gap (clearance) is created between the through vias 45 and the first conductive film 31. The second conductive film 32 of the capacitor 30 has openings 32A having a diameter greater than the diameter of each through via 55 to which the ground potential is supplied so that gap (clearance) is created between the through via 55 and the second conductive film 32.

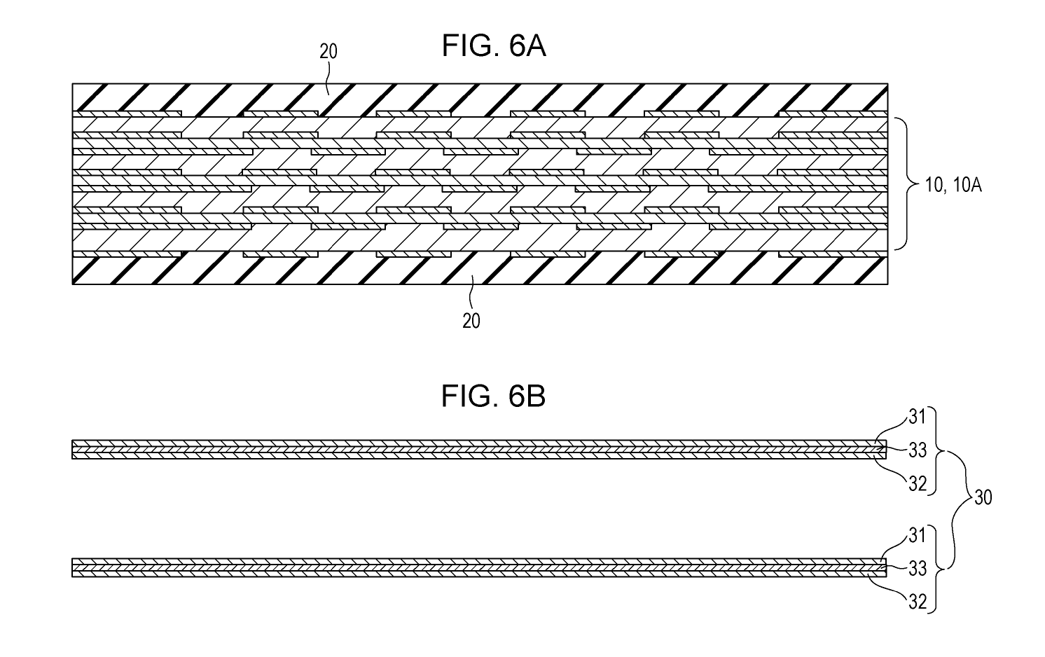

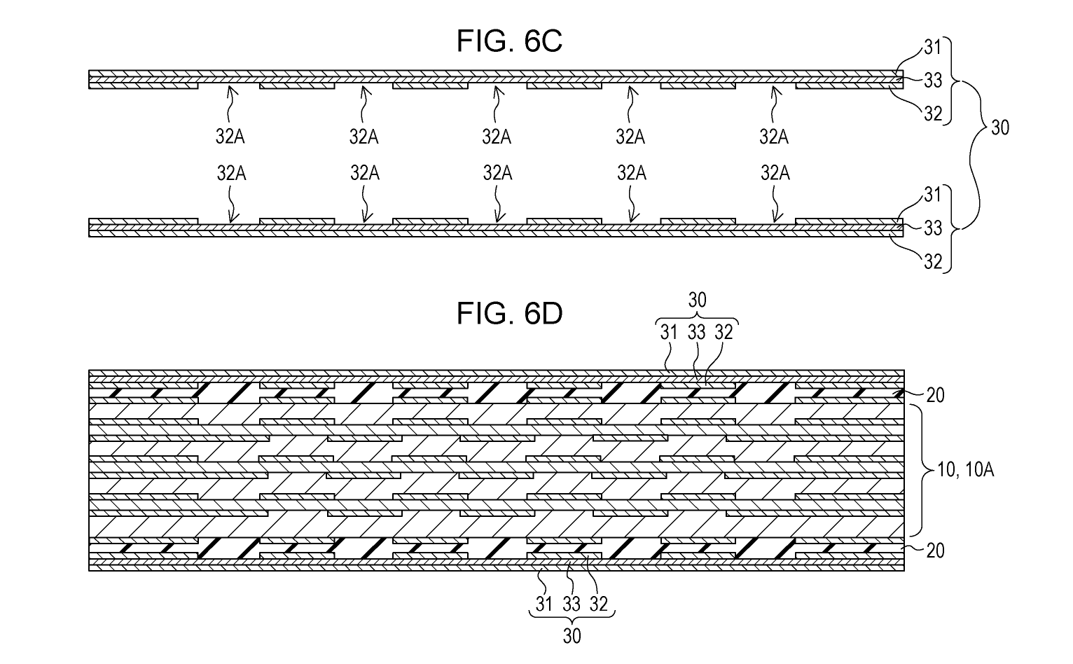

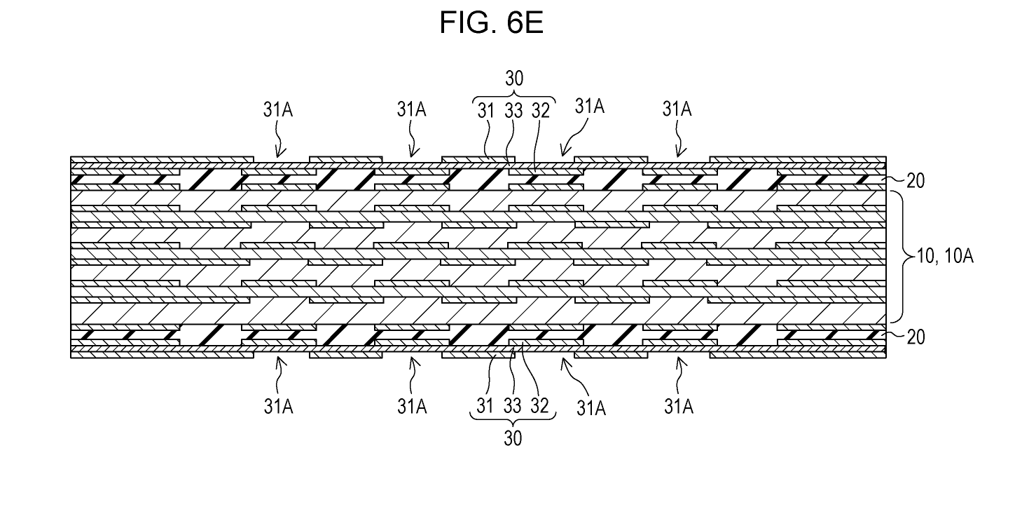

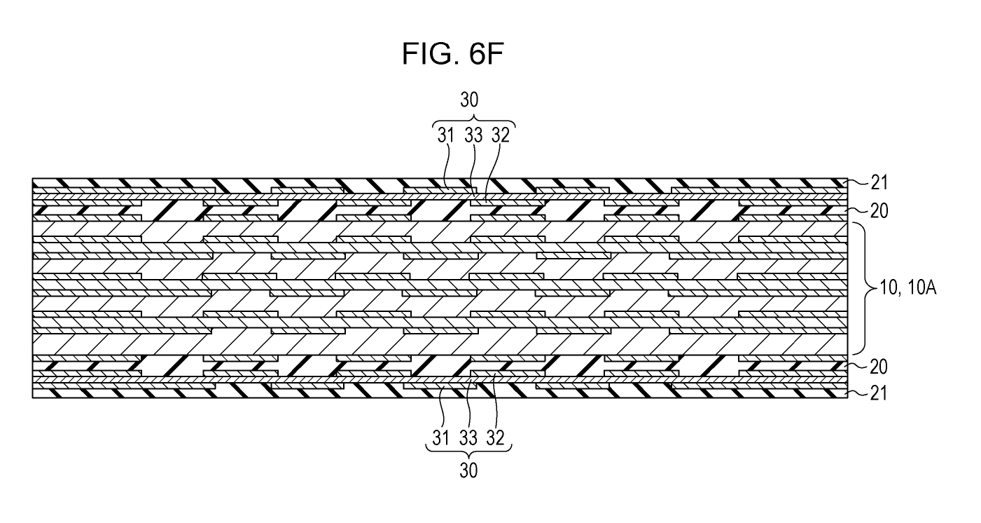

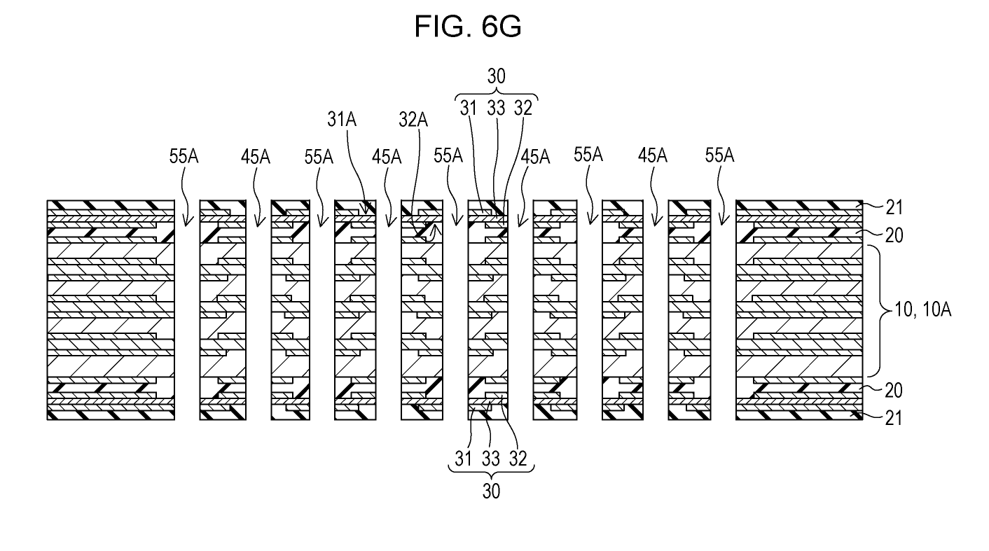

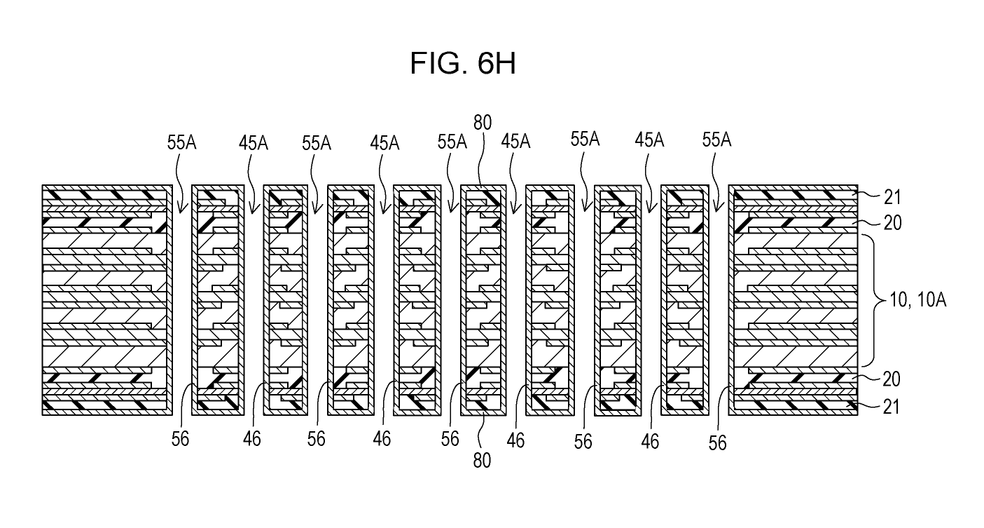

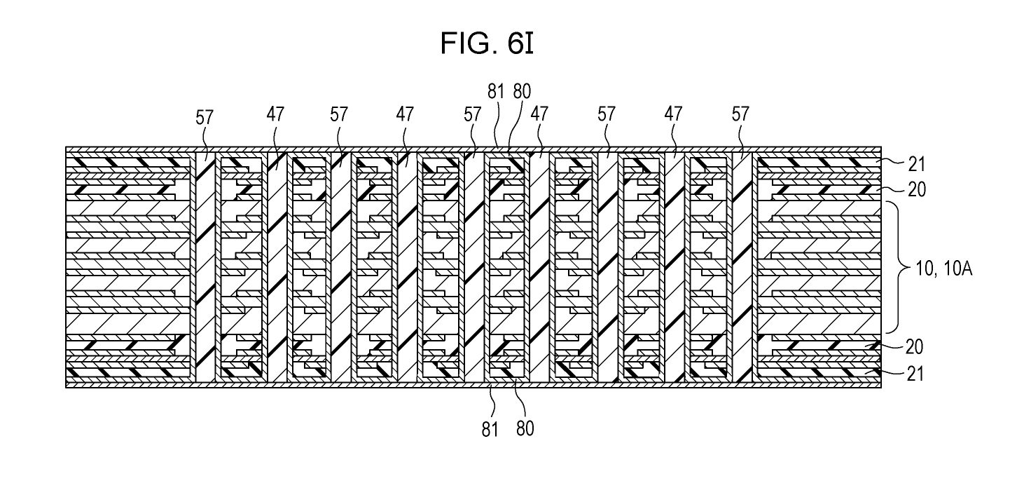

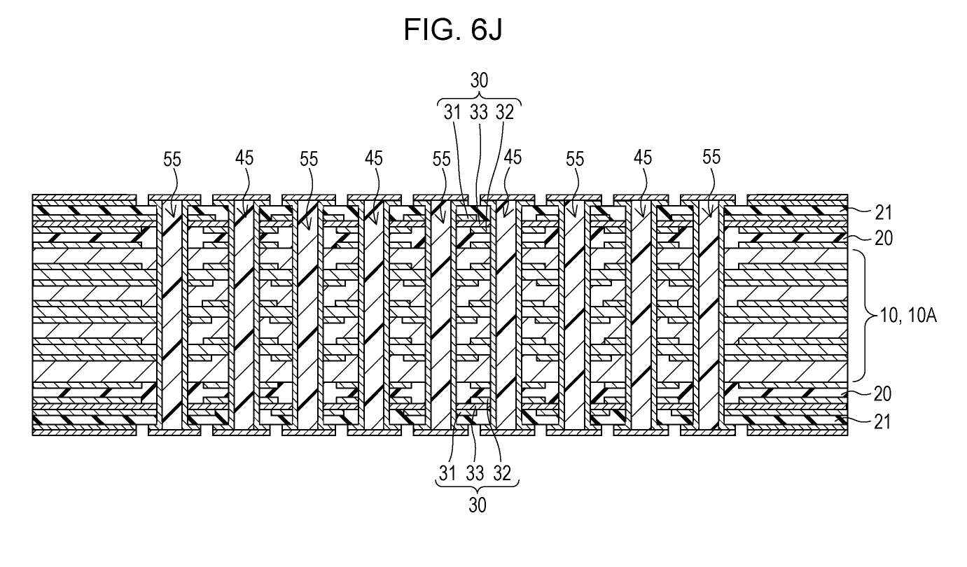

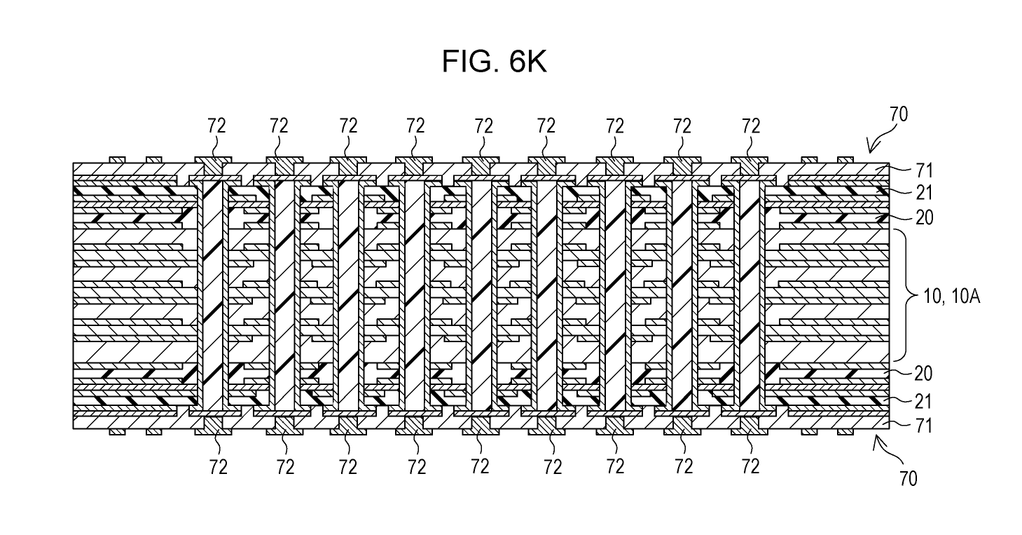

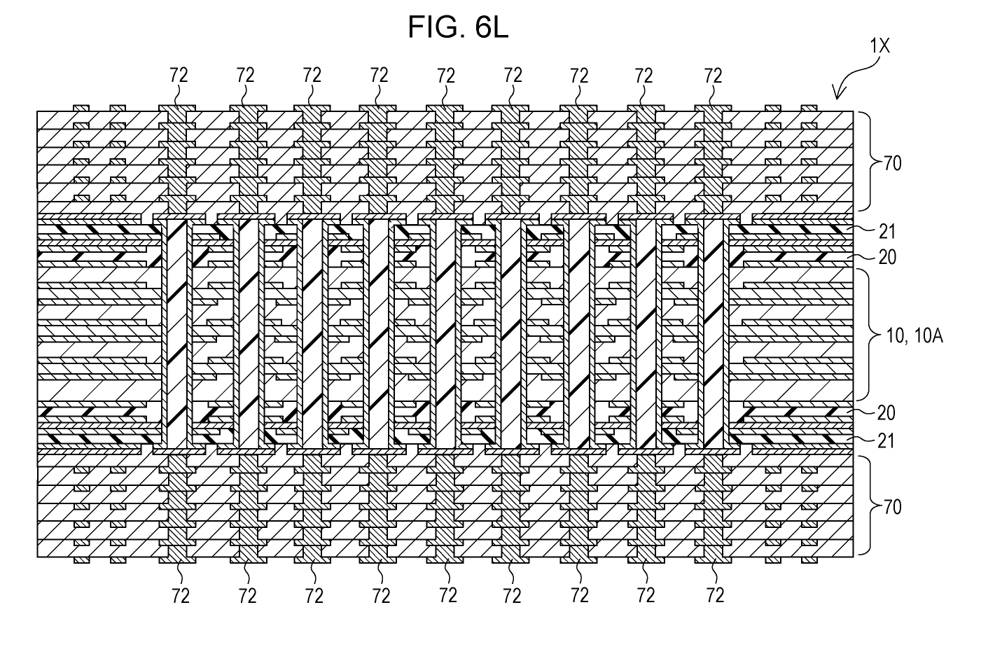

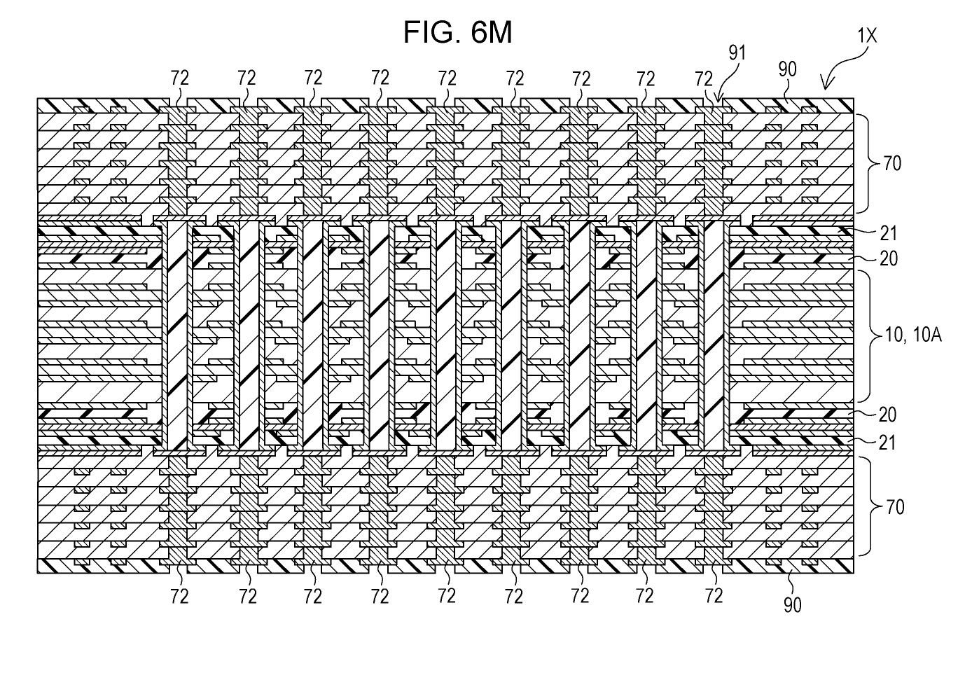

Hereinafter, a method of manufacturing the wiring substrate 1X according to a comparative example will be described. FIGS. 6A to 6M are each a cross-sectional view illustrating an example of a method of manufacturing the wiring substrate 1X according to a comparative example.

First, the base substrate 10 which serves as the core layer 10A is formed by the same method as the method of manufacturing the wiring substrate 1 according to the embodiment of the technique of the present disclosure. Subsequently, an insulating film 20 is formed, for example, by a vacuum lamination method on both sides of the base substrate 10 which serves as the core layer 10A (FIG. 6A).

Subsequently, a thin film capacitor 30 is prepared, in which the first conductive film 31, the dielectric film 33, and the second conductive film 32 are stacked (FIG. 6B). The power supply potential is applied to the second conductive film 32, and the ground potential is applied to the first conductive film 31.

Subsequently, the second conductive film 32 of the capacitor 30, disposed inwardly in the thickness direction of the base substrate 10 is patterned. Openings 32A are formed in the second conductive film 32, each having a diameter greater than the diameter of each through via 55 to which the ground potential is supplied and which is formed in the later process so that gap (clearance) is created between the second conductive film 32 and the through via 55. The diameter of each opening 32A includes a margin in consideration of position displacement when the capacitor 30 is affixed to the base substrate 10 (FIG. 6C).

Subsequently, the capacitor 30 is disposed on the insulating film 20. The capacitor 30 covers the entire surface of the base substrate 10 which serves as the core layer 10A. Subsequently, the surface of the capacitor 30 is protected by a PET film (not illustrated), then the capacitor 30 is brought into intimate contact with the insulating film 20, for example, by a vacuum lamination method. Next, the PET film is peeled off, then the insulating film 20 is thermally cured (FIG. 6D).

Subsequently, the first conductive film 31 of the capacitor 30, disposed outwardly in a thickness direction of the base substrate 10 is patterned. Openings 31A are formed in the first conductive film 31, each having a diameter greater than the diameter of each through via 45 to which the power supply potential is supplied and which is formed in the later process so that gap (clearance) is created between the first conductive film 31 and the through via 45 (FIG. 6E).

Subsequently, an insulating film 21 is formed on the surface of the base substrate 10 which serves as the core layer 10A. The surface of the capacitor 30 is covered with the insulating film 21 (FIG. 6F).

Subsequently, multiple through holes 45A included in the multiple through vias 45 and multiple through holes 55A included in the multiple through vias 55 are formed by drilling. The through holes 45A, 55A penetrate the base substrate 10 along with the insulating films 21, 20 and the capacitor 30 provided on both sides of the base substrate 10. The through holes 55A are provided at the position corresponding to the openings 32A formed in the second conductive film 32 so as to pass through the openings 32A. The through holes 45A are provided at the position corresponding to the openings 31A formed in the first conductive film 31 so as to pass through the openings 31A (FIG. 6G).

Subsequently, conductive films 46, 56, which cover the inner walls of the through holes 45A, 55A, respectively, are formed by plating processing. A conductive film 80 is formed on the surface of the insulating film 21 by the plating processing (FIG. 6H).

Subsequently, the insides of the through holes 45A, 55A are filled with insulating materials 47 and 57 such as an epoxy resin. Subsequently, a conductive film 81, which covers the entire surface of the insulating film 21, is formed by plating processing so as to close the opening ends of the through holes 45A, 55A (FIG. 6I).

Subsequently, the conductive films 80 and 81 are patterned. Consequently, through vias 45 are formed, which are electrically coupled to the second conductive film 32 of the capacitor 30, and are insulated from the first conductive film 31 of the capacitor 30. Through vias 55 are formed, which are electrically coupled to the first conductive film 31 of the capacitor 30, and are insulated from the second conductive film 32 of the capacitor 30 (FIG. 6J).

Subsequently, build-up layers 70 are formed on both sides of the base substrate 10 which serves as the core layer 10A. Each build-up layer 70 is formed by formation of the prepreg 71, hole making process, and formation of the wire 72 (FIG. 6K). Multiple build-up layers 70 are stacked on both sides of the core layer 10A as desired. The first through via 40 and the second through via 50 are drawn to the outermost surface of the wiring substrate 1X by wires 72 provided in the build-up layers 70 (FIG. 6L).

Subsequently, a solder resist 90 is formed on the outermost surface of the build-up layers 70. Subsequently, the wires 72 provided on the outermost surface of the build-up layers 70 are exposed by forming openings 91 in the solder resist 90 (FIG. 6M). As a consequence of the above-described processes, the wiring substrate lx according to the comparative example is completed.

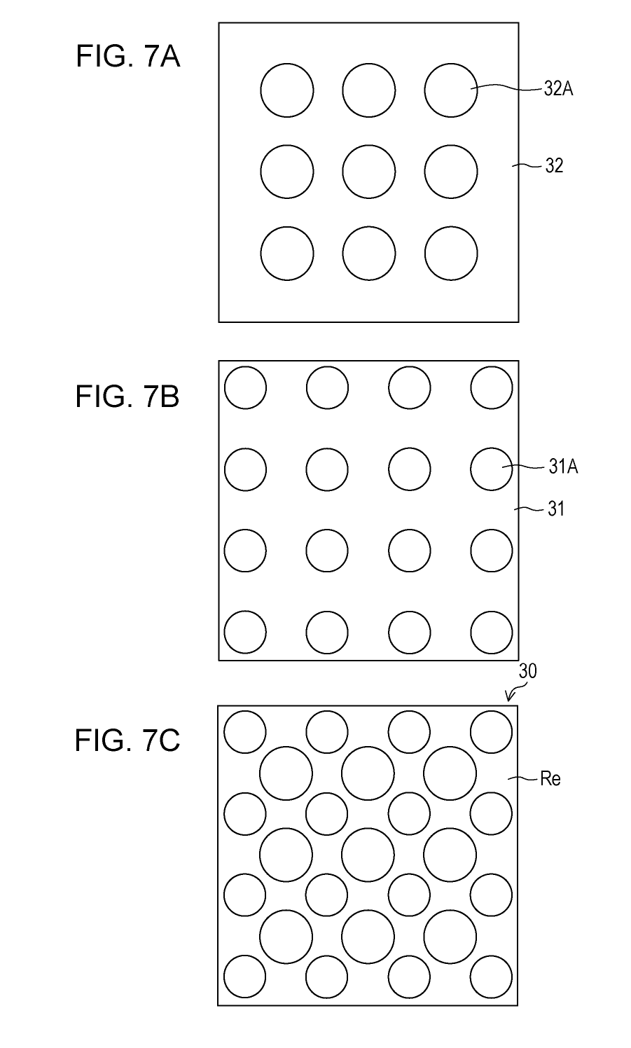

FIG. 7A is a plan view schematically illustrating the openings 32A formed in the second conductive film 32 of the capacitor 30 in the wiring substrate 1X according to the comparative example. FIG. 7B is a plan view schematically illustrating the openings 31A formed in the first conductive film 31 of the capacitor 30 in the wiring substrate 1X according to the comparative example. FIG. 7C is a plan view schematically illustrating an effective area Re of the capacitor 30 in the wiring substrate 1X according to the comparative example.

In the wiring substrate 1X according to the comparative example, as illustrated in FIG. 7A, in the second conductive film 32 of the capacitor 30, openings 32A are formed, each having a diameter greater than the diameter of each through via 55 to which the ground potential is supplied so that gap (clearance) is created between the through via 55 and the second conductive film 32. In the wiring substrate 1X according to the comparative example, as illustrated in FIG. 7B, in the first conductive film 31 of the capacitor 30, openings 31A are formed, each having a diameter greater than the diameter of each through via 45 to which the power supply potential is supplied so that gap (clearance) is created between the through via 45 and the first conductive film 31. The diameter of each opening 32A formed in the second conductive film 32 preferably has a margin in consideration of position displacement when the capacitor 30 is affixed to the base substrate 10. Therefore, the diameter of each opening 32A formed in the second conductive film 32 is greater than the diameter of each opening 31A formed in the first conductive film 31.

In the wiring substrate 1X according to the comparative example, an effective area Re of the thin film capacitor 30 is the area where the first conductive film 31 and the second conductive film 32 overlap as illustrated by hatching in FIG. 7C. In other words, the effective area Re is the area excluding the formation area of the openings 31A and the formation area of the openings 32A. Therefore, when the openings 31A, 32A as the clearance for the through vias 45 and 55 are respectively provided in the first conductive film 31 and the second conductive film 32, the effective area Re is reduced. As a consequence, in the wiring substrate 1X according to the comparative example, the cost of the capacitor 30 increases.

In contrast, in the wiring substrate 1 according to the embodiment of the technique of the present disclosure, the first through via 40 provided in the formation area R1 of the capacitor 30 is electrically coupled to the second conductive film 32 of the capacitor 30, and is insulated from the first conductive film 31 of the capacitor 30. The second through via 50 provided in the non-formation area R2 of the capacitor 30 is electrically coupled to the first conductive film 31 of the capacitor 30, and is insulated from the second conductive film 32 of the capacitor 30. For example, in the wiring substrate 1 according to the embodiment of the technique of the present disclosure, the through vias, which penetrate the capacitor 30, include only the first through vias 40 which are electrically coupled to the second conductive film 32, and are insulated from the first conductive film 31. Therefore, the openings 31A as the clearance for the first through vias 40 have to be provided in the first conductive film 31 only, and clearance for the through vias do not have to be provided in the second conductive film 32, thus openings do not have to be formed. Therefore, in the wiring substrate 1 according to the embodiment of the technique of the present disclosure, it is possible to increase the effective area of the capacitor 30, as compared with the wiring substrate 1X according to the comparative example. In the wiring substrate 1 according to the embodiment of the technique of the present disclosure, it is possible to improve the area utilization efficiency of the capacitor 30 by approximately 30%, as compared with the wiring substrate lx according to the comparative example.

In the wiring substrate 1 according to the embodiment of the technique of the present disclosure, as illustrated in FIG. 1, the capacitor 30 has the area R3, in which the first conductive film 31 is not formed, on the outer periphery. For example, the outer periphery of the capacitor 30 has a two-layer structure including the dielectric film 33 and the second conductive film 32. With this structure, it is possible to reduce the risk of occurrence of short-circuit between the power supply and the ground due to contact between the first conductive film 31 and the second conductive film 32 at an end face of the capacitor 30.

In the wiring substrate 1 according to the embodiment of the technique of the present disclosure, as illustrated in FIG. 3, part of the multiple first through vias 40 is provided at a position corresponding to the outer periphery of the capacitor 30. Patterning of the first conductive film 31 of the capacitor 30 is performed after the capacitor 30 is affixed to the base substrate 10, and the first through vias 40 are formed. This makes it possible to relax desired accuracy for positioning of the capacitor 30 and the base substrate 10 when the capacitor 30 is affixed to the base substrate 10.

In the wiring substrate 1 according to the embodiment of the technique of the present disclosure, the interval between the multiple IVHs 61 is smaller than the interval between the multiple first through vias 40. The number of multiple IVHs 61 is larger than the number of multiple first through vias 40. For example, the multiple IVHs 61 are formed with a higher density than that of the multiple first through vias 40. Therefore, it is possible to reduce the inductance of a current path coupled to the first conductive film 31 of the capacitor 30, and the function of the capacitor 30 as the decoupling capacitor may be maximized.

In the wiring substrate 1 according to the embodiment of the technique of the present disclosure, as illustrated in FIG. 2, the capacitor 30 is provided on both sides near the first surface S1 and near the second surface S2 of the base substrate 10. Therefore, the structure of the wiring substrate 1 is symmetric with respect to the thickness direction of the wiring substrate 1, and thus it is possible to reduce warpage of the wiring substrate 1 due to heat.

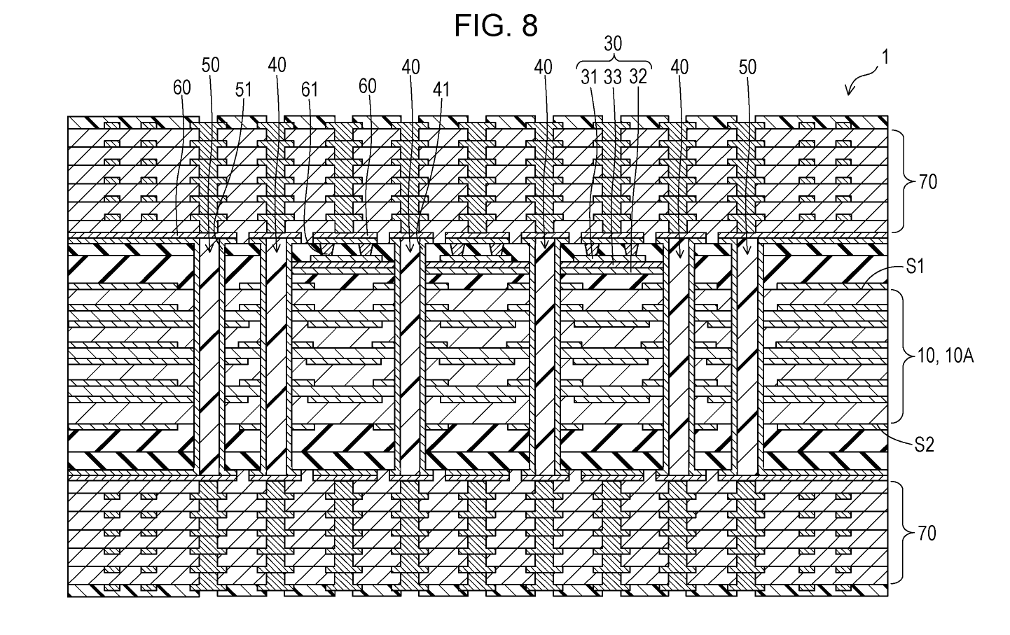

As illustrated in FIG. 8, the capacitor 30 may be provided only on one side of the base substrate 10. In the embodiment, a case has been illustrated where the connection wire 60, which electrically connects the second through via 50 and the first conductive film 31 of the capacitor 30, is formed by the conductive films 80 and 81 formed on the outermost surface of the core layer 10A (see FIG. 4L). However, the present disclosure is not limited to the embodiment. The connection wire 60 may be formed by the wires 72 which are formed in the build-up layers 70, for example. The connection wire 60 may be formed by both the conductive films 80, 81 formed on the outermost surface of the core layer 10A and the wires 72 formed in the build-up layers 70.

### Second Embodiment

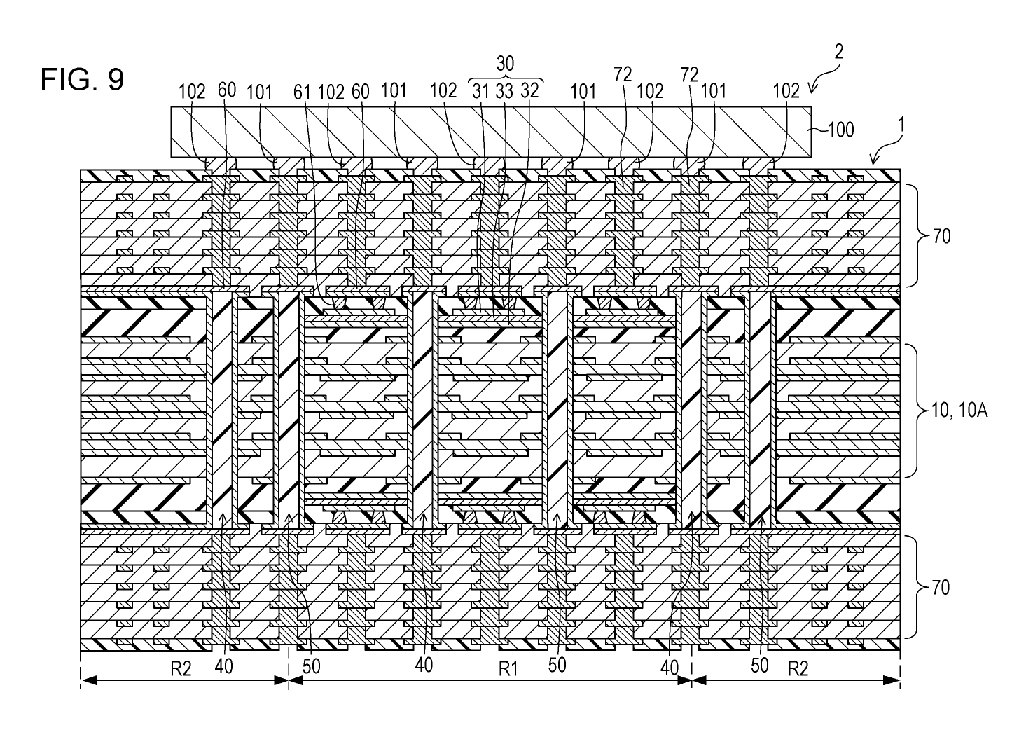

FIG. 9 is a cross-sectional view illustrating an example of the configuration of a semiconductor module 2 according to a second embodiment of the technique of the present disclosure. The semiconductor module 2 includes a wiring substrate 1, and a semiconductor chip 100 mounted on the wiring substrate 1. The semiconductor chip 100 may include, for example, an integrated circuit included in a CPU.

The semiconductor chip 100 has first terminals 101 electrically coupled to the first through vias 40 via the build-up layers 70, and second terminals 102 electrically coupled to the second through vias 50 via the build-up layers 70. For example, the first terminals 101 are electrically coupled to the second conductive film 32 of the capacitor 30, and the second terminals 102 are electrically coupled to the first conductive film 31 of capacitor 30. The first terminals 101 and the second terminals 102 may be each a solder bump.

The semiconductor chip 100 is provided at a position overlapping with the formation area R1 of the capacitor 30, in other words, just above the capacitor 30. The first terminals 101 of the semiconductor chip 100 are each provided at a position with the shortest distance from a first through via 40, in other words, just above a first through via 40. The second terminals 102 of the semiconductor chip 100 are each provided at a position with the shortest distance from the first conductive film 31 of the capacitor 30, in other words, just above the first conductive film 31. The wires 72 provided in the build-up layers 70 connect each of the first terminals 101 of the semiconductor chip 100 and a corresponding first through via 40 by a shortest path, and connect each of the second terminals 102 of the semiconductor chip 100 and a corresponding first conductive film 31 of the capacitor 30 by a shortest path.

With the semiconductor module 2 according to the embodiment of the technique of the present disclosure, in the configuration in which the through vias and the capacitor 30 are disposed in the area just below the semiconductor chip 100, it is possible to maximize the effective area of the capacitor 30 and thus to improve the area utilization efficiency of the capacitor 30.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A wiring substrate comprising:
a base substrate;
a film capacitor that includes a first conductive film disposed over a surface of the base substrate, a second conductive film, and a dielectric film disposed between the first conductive film and the second conductive film;
a first through via that is disposed in the base substrate, penetrates the base substrate and the capacitor, is electrically coupled to the second conductive film, and is insulated from the first conductive film; and
a second through via that is disposed in the base substrate, penetrates the base substrate, is electrically coupled to the first conductive film, and is insulated from the second conductive film.

2. The wiring substrate according to claim 1,
wherein an outer size of the capacitor is smaller than an outer size of the base substrate.

3. The wiring substrate according to claim 1, further comprising:
an insulating film that covers a surface of the first conductive film;
a connection wire that is disposed on a surface of the insulating film, and is electrically coupled to the second through via; and
a plurality of interstitial via holes that are disposed within the insulating film, and that electrically connect the connection wire and the first conductive film.

4. The wiring substrate according to claim 3,
wherein the wiring substrate includes a plurality of first through vias, each of the plurality of first through vias is the first through via, and
an interval between the plurality of interstitial via holes is smaller than an interval between the plurality of first through vias.

5. The wiring substrate according to claim 3,
wherein the wiring substrate includes a plurality of first through vias, each of the plurality of first through vias is the first through via, and
a number of the plurality of interstitial via holes is larger than a number of the plurality of first through vias.

6. The wiring substrate according to claim 1,
wherein an area of the first conductive film is smaller than an area of the dielectric film.

7. The wiring substrate according to claim 1,
wherein the second conductive film is bonded to the dielectric film over an entire surface of the dielectric film, and
the first conductive film has clearance between the first through via and the first conductive film, and is bonded to the dielectric film.

8. The wiring substrate according to claim 1,
wherein the wiring substrate includes a plurality of capacitors, each of which is the capacitor, and
a first capacitor of the capacitors is disposed on a first insulating film on a first side of the base substrate, and a second capacitor of the capacitors is formed on a second side of the base substrate opposite the first side.

9. The wiring substrate according to claim 1,
wherein the wiring substrate includes a plurality of first through vias, each of which is the first through via, and
part of the plurality of first through vias is coupled to an outer periphery of the second conductive film of the capacitor.

10. The wiring substrate according to claim 1,
wherein the wiring substrate includes the base substrate as a core layer, and
a build-up layer disposed on a first surface of an insulating filing on the base substrate which includes the capacitor, the build-up layer including a wire.

11. A semiconductor module comprising:
a wiring substrate; and
a semiconductor chip mounted on the wiring substrate,
wherein the wiring substrate includes:
a base substrate;
a film capacitor that includes a first conductive film disposed over a surface of the base substrate, a second conductive film, and a dielectric film disposed between the first conductive film and the second conductive film;
a first through via that is disposed in the base substrate, penetrates the base substrate and the capacitor, is electrically coupled to the second conductive film, and is insulated from the first conductive film; and
a second through via that is disposed in the base substrate, penetrates the base substrate, is electrically coupled to the first conductive film, and is insulated from the second conductive film, and
wherein the semiconductor chip includes:
a first terminal electrically coupled to the first through via, and
a second terminal electrically coupled to the second through via.

12. The semiconductor module according to claim 11,
wherein an outer size of the capacitor is smaller than an outer size of the base substrate.

13. The semiconductor module according to claim 11, further comprising:
an insulating film that covers a surface of the first conductive film;
a connection wire that is disposed on a surface of the insulating film, and is electrically coupled to the second through via; and
a plurality of interstitial via holes that are disposed within the insulating film, and that electrically connect the connection wire and the first conductive film.

14. The semiconductor module according to claim 13,
wherein the semiconductor module includes a plurality of first through vias, each of which is the first through via, and
an interval between the plurality of interstitial via holes is smaller than an interval between the plurality of first through vias.

15. The semiconductor module according to claim 13,
wherein the semiconductor module includes a plurality of first through vias, each of which is the first through via, and
a number of the plurality of interstitial via holes is larger than a number of the plurality of first through vias.

16. The semiconductor module according to claim 11,
wherein an area of the first conductive film is smaller than an area of the dielectric film.

17. The semiconductor module according to claim 11,
wherein the second conductive film is bonded to the dielectric film over an entire surface of the dielectric film, and
the first conductive film has clearance between the first through via and the first conductive film, and is bonded to the dielectric film.

18. The semiconductor module according to claim 11,
wherein the capacitor is disposed near a first surface of the base substrate, and near a second surface on an opposite side to the base substrate from the first surface.

19. A manufacturing method for a wiring substrate, the method comprising:
providing a base substrate;
forming a film capacitor that includes a first conductive film disposed over a surface of the base substrate, a second conductive film, and a dielectric film disposed between the first conductive film and the second conductive film;
forming a first through via that is disposed in the base substrate, penetrates the base substrate and the capacitor, is electrically coupled to the second conductive film, and is insulated from the first conductive film; and
forming a second through via that is disposed in the base substrate, penetrates the base substrate, is electrically coupled to the first conductive film, and is insulated from the second conductive film.

20. The manufacturing method according to claim 19, further comprising:
forming an insulating film on the surface of the base substrate;
forming a connection wire that is disposed on a surface of the insulating film, and is electrically coupled to the second through via; and
forming a plurality of interstitial via holes that are disposed internally of the insulating film, and that electrically connect the connection wire and the first conductive film.

21. A wiring substrate comprising:
a base substrate;
a film capacitor that includes a first conductive film disposed over a surface of the base substrate, a second conductive film, and a dielectric film disposed between the first conductive film and the second conductive film;
a first through via that is disposed in the base substrate, penetrates the base substrate and the capacitor, is electrically coupled to the second conductive film, and is insulated from the first conductive film; and
a second through via that is disposed in the base substrate, penetrates the base substrate, is electrically coupled to the first conductive film, and is insulated from the second conductive film, wherein
the second through via does not penetrate the capacitor.
